(19) United States
(12) Patent Application Publication
(10) Pub. No.: US 2007/0233409 A1
(43) Pub. Date: Oct. 4, 2007

(54) Spectrum analyzer with cascadable trace math functions

(76) Inventors: Corydon Joseph Boyan, Santa Rosa, CA (US); Rick Thomas Lund, Windsor, CA (US); Joseph Michael Gorin, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/397,517

(22) Filed: Apr. 4, 2006

(51) Int. Cl. G06F 19/00; G01R 23/16; G06F 17/40

(52) U.S. Cl. 702/76; 702/1; 702/57; 702/66; 702/75; 702/77; 702/127; 702/189; 702/85; 702/187; 324/76.11; 324/76.19; 324/76.21; 324/76.22

(57) ABSTRACT

A spectrum analyzer is disclosed. The analyzer includes a detector, a trace memory, a controller, a trace math processor and a display. The controller generates a plurality of frequency selection signal values and records the measured amplitudes at each of the generated frequency selection values to form a measured trace that is stored in slots in the trace memory. The trace math processor performs trace mathematical operations on traces stored in the trace memory to generate a math trace that is stored in the trace memory. The controller stores a plurality of trace math programs, each program corresponding to one of the trace storage slots in the trace memory and specifies the trace mathematical operations that are to be performed to generate a new trace to be stored in that trace storage slot. The controller executes the stored trace math program for each trace slot in a predetermined order.

### BACKGROUND OF THE INVENTION

Spectrum analyzers provide a display of the amplitude versus frequency of the various frequency components of a signal input thereto. For the purposes of this discussion, the term “trace” is defined to be a sequence of values that are processed together. For example, the set of measured values of the amplitude as a function of frequency that is displayed by a spectrum analyzer is one example of a trace. It should be noted that the values could be scalars such as the amplitude of the signal discussed above or vector valued. For example, a sequence of (I,Q) values for an RF signal as a function of frequency can also be a trace if the values are processed together.

Spectrum analyzers are essential tools for the analysis of complex communication systems and the like. As the systems under analysis become more complex, a simple graph of amplitude versus frequency is often inadequate to diagnose problems in the device under test. For complex devices, the raw data collected by the spectrum analyzer may require mathematical processing to provide information that is meaningful to a system designer or technician working on the device under test. In principle, the traces collected by the spectrum analyzer can be off-loaded to a suitable computer for analysis and display. However, such serial processing of the data is problematic in environments in which the analysis is used to make adjustments to the device under test followed by new data collection and processing. Hence, spectrum analyzers that are capable of processing the traces and displaying the processed traces are needed.

The mathematical processing that has been available on spectrum analyzers has been quite limited and often provides outputs that are of little use to a system designer. For example, prior art spectrum analyzers that subtract two traces to provide a processed trace are known to the art. In such a system, a calibration trace is first measured and stored in the spectrum analyzer. When a new trace is measured, the corresponding entry in the calibration trace is subtracted from each measured value to provide a corrected trace that is stored in the spectrum analyzer and displayed. However, even this limited form of processing is flawed for many applications. First, the measured values are replaced by the processed values, and hence, the user has no means for viewing the raw measured data. Second, the measured values provided by the spectrum analyzer are typically the logarithm of the amplitude of the input signal as a function of frequency. In these prior art systems, the difference computation is performed on these logarithmic values rather than the underlying signal amplitudes. Hence, the resultant processed trace is related to the ratio of the signal intensities rather than the difference of the calibration and measured signal amplitudes. Accordingly, the processed trace is not easily used to determine the signal amplitude or power.

### SUMMARY OF THE INVENTION

The present invention includes a spectrum analyzer and a method for operating a spectrum analyzer. The spectrum analyzer includes a detector, a trace memory, a controller, a trace math processor and a display. The detector measures an amplitude of an input signal at a frequency determined by a frequency selection signal. The controller generates a plurality of frequency selection signal values and records the measured amplitudes at each of the generated frequency selection values to form a measured trace. The trace memory includes a plurality of trace storage slots, each trace storage slot storing one of the traces. The trace math processor performs trace mathematical operations on traces stored in the trace memory to generate a math trace that is stored in the trace memory. The display displays selected traces stored in the trace memory. The controller stores a plurality of trace math programs, each trace math program corresponding to one of the trace storage slots in the trace memory and specifying the trace mathematical operations that are to be performed to generate a new trace to be stored in that trace storage slot. The controller executes the stored trace math program for each trace slot in a predetermined order. In one aspect of the invention, one of the trace math programs also causes the current measured trace to be stored in one of the slots in the trace memory. In another aspect of the invention, one of the stored trace math programs utilizes a plurality of traces stored in the trace memory and an offset value as input to the trace math processor. In another aspect of the invention, trace math operations generate average, maximum, and minimum power differences and power sum traces.

### BRIEF DESCRIPTION OF THE DRAWINGS

FIG. 1 is a simplified block diagram of a spectrum analyzer according to one embodiment of the present invention.

FIG. 2 is a block diagram of another embodiment of a spectrum analyzer according to the present invention.

FIG. 3 is also a block diagram of another embodiment of a spectrum analyzer according to the present invention.

FIG. 4 is a flow chart of the processing algorithm executed by the controller during each processing cycle.

### DETAILED DESCRIPTION OF PREFERRED EMBODIMENTS OF THE PRESENT INVENTION

For the purposes of the following discussion, the following definitions apply. The terms “trace mathematical operation” or “trace math operation” are defined to be a mathematical function or algorithm that generates an output trace from one or more input traces. That is, Tₒᵤₜ=F(T₁, T₂, . . . ) where Tₒᵤₜ, T₁, T₂, . . . are traces having N elements, where N>0, and F denotes a fluction or computer algorithm. The I^{th} element of a trace T will be denoted by T[I]. A cascadable trace math function is one for which Tₒᵤₜ[I]=G(T₁[I], T₂[I], . . . ) for I=1 to N. Here G denotes a function or computer algorithm. It should be noted that the elements of an output trace that result from a cascadable trace math function can be computed before all of the elements of the input traces are known. That is, the I^{th} element of the output trace can be computed as soon as the I^{th} elements of the input traces are known.

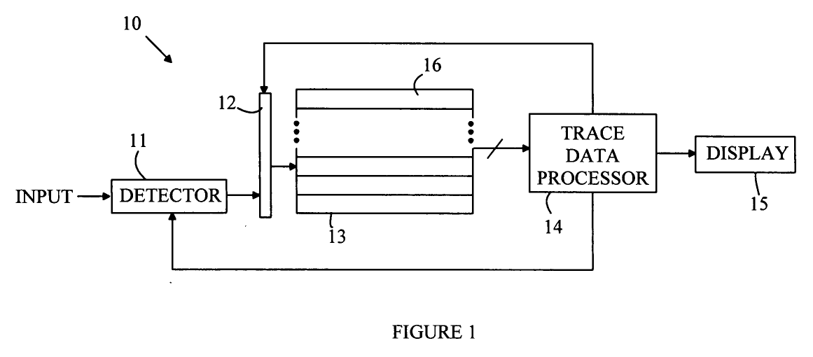

The manner in which the present invention provides its advantages can be more easily understood with reference to FIG. 1, which is a simplified block diagram of a spectrum analyzer 10 according to one embodiment of the present invention. The present invention operates on traces as defined above. A trace can be the result of a series of measurements of an input signal by a detector 11 or the result of a trace math function having inputs that are previously processed traces. The currently active traces are stored in a trace memory 13. Each trace is stored in a slot 16 that is identified by an address or other form of indexing in trace memory 13. Each trace is associated with a program that is stored in trace data processor 14. As will be explained in more detail below, during any given processing cycle, these programs are executed in a predetermined order. Each trace in trace memory 13 can also include a plurality of storage locations that are used to store other values associated with that trace such as the scaling factor to use when displaying that trace.

If the data for the currently active trace is to be taken from a detector such as detector 11, then trace data processor 14 operates the detector and stores the measurements in the corresponding slot in trace memory 13 via an interface circuit 12. Such detectors are known to the art, and hence, will not be discussed in detail here. For the purposes of the present discussion, it is sufficient to note that in one class of detectors, the input signal is mixed with a signal from a local oscillator whose frequency is controlled by trace data processor 14 to generate an intermediate frequency signal that is processed by a bandpass filter to produce a signal that is then envelope-detected. The output of the envelope detector is then digitized to produce a value representing the amplitude of the input signal at the frequency of the local oscillator. Trace data processor 14 sweeps the local oscillator signal through a range of values to generate the individual amplitude values for the trace in question.

It should be noted that other types of detectors can also be utilized. For example, a detector that provides the amplitude and phase of the input signal as a function of frequency or a detector that provides some property of the input signal as a function of time could also be utilized. In addition, different traces could utilize different detectors. That is, the single detector shown in FIG. 1 could include sub-detectors that utilize different measurement circuits and algorithms.

As noted above, the source of the data for any particular trace could be an algorithm executed by trace data processor 14 on one or more previously defined traces. To simplify the following discussion, it will be assumed that the traces are indexed from one to M and that trace data processor 14 processes the traces in numerical order. Consider a simple example in which the user wishes to display the difference in signal amplitude between a first and second signal. It will also be assumed that detector 11 provides an output that is a logarithm of the signal amplitude. Such detectors are commonly used to provide an increased dynamic range for display purposes. In this case, the first and second traces could be loaded with the output of detector 11 for the first and second signals, respectively. The third and fourth traces could then be loaded by computing the antilogarithms of the values in the first and second traces respectively to provide traces that store the amplitudes of the signals as opposed to the logarithms of the amplitudes. The fifth trace would then be loaded with the difference of each of the corresponding entries in the third and fourth trace. The sixth trace could then be loaded with the logarithm of the corresponding entries in the fifth trace to provide a trace that is displayed on display 15 or output to an external device. Alternatively, the final trace could be computed from the first and second traces in a single operation in which the antilogarithms of the corresponding elements of the first and second traces are subtracted from one another and then the logarithm of the result is formed and stored in the corresponding element of third trace.

In the above-described embodiments, the traces are processed in their numerical order based on the trace index. The user in this case must assure that the input traces needed to process any given trace are lower in index number than the current trace, and hence, are available when the current trace is processed. However, other orders can be utilized. For example, embodiments in which the user specifies the order of processing as part of the program executed by trace data processor 14 can also be constructed.

In addition, embodiments in which trace data processor 14 determines the proper order in which to process the traces can also be constructed. The same algorithms that are used in spread sheet programs to determine the proper order in which to calculate the functions in the various boxes of the spreadsheet can also be used to determine the order in which the traces of the present invention are to be processed.

In principle, most functions that require serially applying the various math operations can be accomplished in the embodiment shown in FIG. 1 provided a sufficient number of traces can be stored in trace memory 13. For example, the average of the previous traces can be performed in the second trace after the first trace is filled with a new trace. In this case, the value of each entry in the second trace is replaced by its previous value plus the corresponding value in the first trace. The number of traces in the sum in the second trace is stored in a variable associated with that trace and is also updated. The contents of the second trace divided by this value can then be placed in the third trace when that trace is computed so that the third trace can be displayed without changing the display scale.

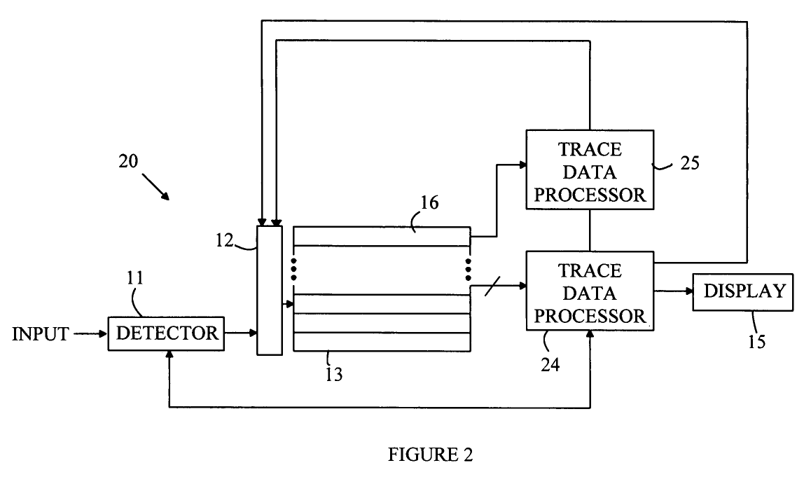

While complex computations can be performed in this manner, the time between the acquisition of a trace and- the completion of all of the computations needed to update the active traces stored in trace memory 13 can be significant. If the number of entries in each trace is large, this serial computational process can significantly slow down the acquisition of data. This drawback is addressed by the embodiment of the present invention shown in FIG. 2, which is a block diagram of another embodiment of a spectrum analyzer 20 according to the present invention. Spectrum analyzer 20 utilizes a pipelined processing arrangement to process traces that require cascaded math processing.

Spectrum analyzer 20 is particularly well suited to situations in which the trace processing is limited to cascadable trace math functions that only involve corresponding entries in two traces. Consider an operation in which a trace is received and the next operation involves computing a new trace, which is the average of the current trace and a number of traces that had arrived earlier. For the purpose of this example, it will be assumed that the detector provides a measurement corresponding to the logarithm of the amplitude of the signal as a function of the frequency of the signal. Denote the current trace by T₁(I) for I=1 to N. That is, T₁(I) is the logarithm of the amplitude of the signal in the I^{th} frequency bin. Similarly, assume that the average trace that is to be updated is stored in T₂(I) for I=1 to N. The update requires that T₂(I) be replaced by
log(log⁻¹(T₂(I))+log⁻¹(T₁(I)) for I=1 to N.
Rather than wait for all of the entries in T₁(I) to arrive, this embodiment of the present invention begins processing T₂(J) as soon as the J^{th} element of T₁ arrives. Hence, each time trace data processor 24 receives an entry from detector 11, trace data processor 24 passes that entry to trace data processor 25, which uses that entry to update the corresponding entry in T₂ while trace data processor 24 stores the new trace element in T. in trace memory 13. That is, while trace data processor 24 is receiving T₁(J), trace data processor 25 is using T₁(J−1).

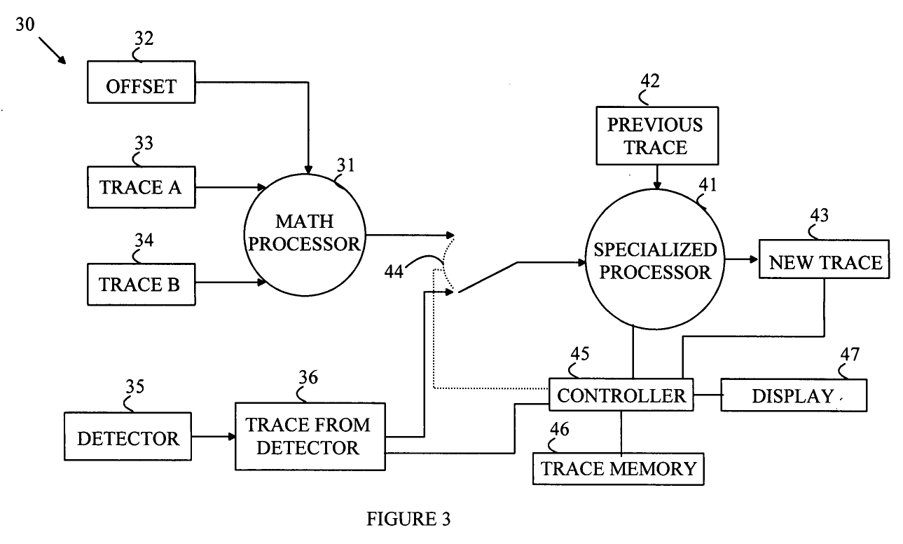

In one embodiment of the present invention, the cascaded processing provides a specific set of functions that are particularly useful in a spectrum analyzer. Refer now to FIG. 3, which is a block diagram of another embodiment of a spectrum analyzer 30 according to the present invention. All of the traces processed by trace math processor 31 are subjected to an optional additional processing provided by specialized processor 41, which operates on the current trace, either from trace math processor 31 or detector 35 and the previously stored values for that trace to generate a new trace 43 that is available to be stored in trace memory 46, displayed on display 47 or output. Specialized processor 41 executes only cascadable math functions, and hence, can commence processing a particular element of a trace as soon as that element is available. The various operations are controlled by controller 45 that includes the processing program that is currently being implemented on the spectrum analyzer. Controller 45 also controls the operations of math processor 31 and the various inputs thereto. To simplify the drawing, these connections have been omitted.

In this embodiment, controller 45 processes the traces in order. When processing is complete for trace 1, trace 2 is processed, and so on, until all of the active traces are processed. This allows the trace that is currently being processed to use any of the previously processed traces as an input to trace math processor 31 when that trace is to be computed.

In the following discussion, the CURRENT TRACE is the trace data that is being processed. The PREVIOUS TRACE is the trace data for the CURRENT TRACE prior to that trace being processed, i.e., the trace data stored in the corresponding slot in trace memory 46 prior to the beginning of the present data acquisition cycle. In general, a spectrum analyzer according to the present invention has a mode in which the analyzer acquires and displays data. This mode is divided into data acquisition cycles that are repeated until the mode is terminated by the user. At the beginning of this mode, the trace memory is typically initialized such that all of the trace slots that are to be used are empty, and the programs that are to be utilized for processing data for each active slot are loaded by the controller together with the identity of each trace that is to be displayed during the display phase of the acquisition cycle.

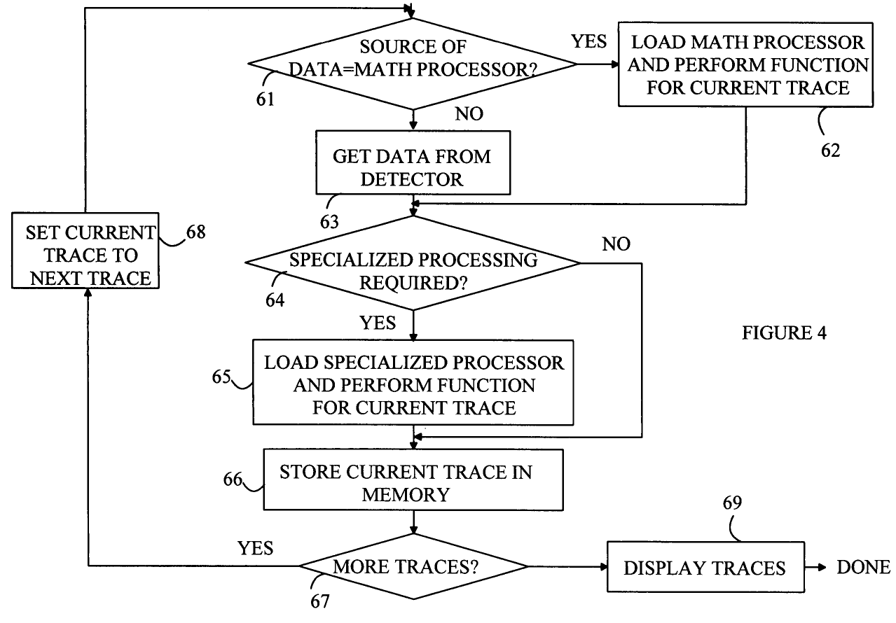

Refer now to FIG. 4, which is a flow chart of the processing algorithm executed by controller 45 during each data acquisition cycle. As noted above, the traces are processed in sequence starting with trace 1 as the CURRENT TRACE. Each trace has a number of parameters that are stored for that trace. The first parameter defines the source of data for that trace. Controller 45 checks the source parameter at the beginning of the processing for the CURRENT TRACE as shown at 61. The source parameter has two values, one indicating that the data is to be taken from detector 35, and one indicating that the source of the data is math processor 31. The data from detector 35 is stored in a signal processor 36 as it is acquired. The source parameter is used to set switch 44 shown in FIG. 3. If the source parameter indicates that the data is to come from detector 35, switch 44 merely routes the data to specialized processor 41.

If the source parameter indicates that the source of the data is math processor 31, then controller 45 loads the appropriate program into math processor 31 and selects the inputs as shown at 62. In this embodiment, math processor 31 operates on, at most, two traces stored in trace memory 46 as defined by the values in registers 33 and 34. However, embodiments that utilize more traces can also be constructed. Math processor 31 also has an offset input 32. A different offset can be set for each trace. The offset is a single value that is input by the user. In general, the output of the math processor for each entry in the output trace is a function of the corresponding entries in the input traces and the offset. The user programs controller 45 with the specific functions for each trace. Some exemplary functions will be discussed in more detail below. Once the math processor is loaded, the trace values are processed in sequence and fed to specialized processor 41. If the trace is to be furnished by the detector, then the trace is acquired from the interface 36 in which the measured trace is stored as shown at 63.

Each trace has a second processing parameter associated with that trace that indicates whether or not the trace is to be operated on by specialized processor 41. Controller 45 checks this parameter at the beginning of the processing for the CURRENT TRACE as shown at 64. If this parameter is set to the value that indicates that specialized processing is to be performed, controller 45 loads the specialized processor with the program for the trace in question as shown at 65.

Specialized processor 41 operates on the trace in a pipelined fashion similar to that discussed above. As soon as the input data to specialized processor 41 is received for each point in the trace, specialized processor 41 operates on that point to generate an output point that is stored in the corresponding point in the CURRENT TRACE as shown at 65.

The CURRENT TRACE values are then stored back in trace memory 46 as shown at 66. Controller 45 then checks to see if there are more traces to process as shown at 67. If there is an additional trace to be processed, the pointer indicating the identity of the CURRENT TRACE is incremented as shown at 68, and the process is repeated until all of the traces have been processed.

When all of the traces have been processed, controller 45 displays specific traces on display 47 as shown at 69 in the flow chart, and the cycle is then complete. Each trace has a display value stored therewith. If the display value has a predetermined value, that trace is to be displayed on display 47 at a predetermined position. Hence, at the end of a cycle, all of the desired traces are shown on display 47.

In this embodiment, specialized processor 41 has four possible functions. The first function is to do nothing. In this case, the output value in new trace 43 for each point in the CURRENT TRACE is the same as the input value to specialized processor 41.

The remaining three functions utilize the values in the PREVIOUS TRACE and the CURRENT TRACE as inputs and generate a new value that is stored back in trace memory 46. The first of these three functions is an averaging function. In this case, the running average is stored in the corresponding trace. Assume that trace 1 is to be the average of the traces acquired by detector 36. In this case, the source of the data for trace 1 is set to detector 35, and the specialized processor is set to perform an average. The previous trace shown at 42 is the current contents of the slot for trace 1 in trace memory 46. As each point is received by specialized processor 41, the new point is added to the value stored for the previous trace at the corresponding location. The new sum is then stored back in the corresponding point in the slot in memory 46 corresponding to trace 1. If detector 35 outputs the logarithm of the signal amplitude, then the inverse logarithm of the amplitudes are taken before the values are added and the logarithm of the new sum is stored back in the corresponding point in the memory slot in question.

The other two functions executed by specialized processor 41 are the maximum and minimum traces corresponding to the input trace. Consider the case in which the maximum of the trace is to be computed and stored in trace 2. When trace 2 is processed, the input to specialized processor 41 would be set to indicate the data from detector 35. Each data point would be compared with the value stored at the corresponding point in trace 2 in the memory. If the value from detector 35 is greater than the stored value for that point, the value from detector 35 becomes the new value stored at that point in trace memory 46. If not, the old value is returned to that point in trace memory 46.

The minimum function operates in an analogous fashion. In this case, the old value is replaced if the input value is less than the value stored at the corresponding point in trace memory 46.

In the above examples, the specialized processing operated on data from the detector to provide the average and extremes of the traces. However, the specialized processing can be used to provide the average, maximum and minimum for traces that are generated by performing the math functions of math processor 31 on data that was collected from detector 35.

Other specialized functions can be provided by the specialized function processor. The above-described specialized functions are examples of a class of functions that will be referred to as “accumulation functions”. An accumulation function is a cascadable math function that has the CURRENT TRACE and the PREVIOUS TRACE as its inputs. In principle, other accumulation functions can be assigned to specialized processor 41.

In the above-described examples, a single detector is utilized. However, embodiments in which a plurality of detectors are provided or in which the detector has multiple outputs such as the amplitudes of the in-phase and quadrature components of an RF signal as a function of frequency can be constructed.

In principle, math processor 31 can be programmed to provide a large variety of functions. However, some specific functions are particularly useful in the context of a spectrum analyzer. One such set of functions calculates the power difference or sum between the First Trace operand and the Second Trace operand and puts the result in the destination trace. The following formula is executed for each point in the trace operands, and the corresponding point is generated for the destination trace.
DestinationTrace=10 log(10^{(1/10)(FirstTrace)}±10^{(1/10)(SecondTrace)}
Here, all of values of the trace points are assumed to be stored in a decibel scale.

Another useful trace math function is referred to as the Log Offset trace. Here, the destination trace is given by
DestinationTrace=FirstTrace+Offset.
The values of the trace points are assumed to be stored in dBm and the offset is in dB.

A fourth useful math function is referred to as the Log Diff function. This offsets the difference between the First Trace operand and the Second Trace operand by a reference and puts the result in the destination trace, i.e.,
Destination Trace=(FirstTrace−SecondTrace)+Reference.
Each destination trace has its own reference value, which is a single value that is added to each entry. The values of the operand trace points are assumed to be stored in any absolute or relative decibel units, such as dB, dBm, or dBmV, and the reference and result are in dBm.

Various modifications to the present invention will become apparent to those skilled in the art from the foregoing description and accompanying drawings. Accordingly, the present invention is to be limited solely by the scope of the following claims.

What is claimed is:

1. A spectrum analyzer comprising:
a detector that measures an amplitude of an input signal at a frequency determined by a frequency selection signal;
a controller that generates a plurality of frequency selection signal values and records said measured amplitudes at each of said generated frequency selection values to form a measured trace;
a trace memory comprising a plurality of trace storage slots, each trace storage slot storing one of said traces;
a trace math processor that performs trace mathematical operations on said traces stored in said trace memory to generate a math trace that is stored in said trace memory; and
a display that displays traces stored in said trace memory, wherein said controller stores a plurality of trace math programs, each trace math program corresponding to one of said trace storage slots in said trace memory and specifying said trace mathematical operations that are to be performed to generate a trace to be stored in that trace storage slot and wherein said controller executes said stored trace math program for each trace slot in a predetermined order.

2. The spectrum analyzer of claim 1 wherein said controller displays selected ones of said traces in said trace memory after all of said trace math programs have been executed.

3. The spectrum analyzer of claim 1 wherein one of said trace math programs causes said measured trace to be stored in one of said slots in said trace memory.

4. The spectrum analyzer of claim 1 wherein one of said stored trace math programs utilizes a plurality of traces stored in said trace memory and an offset value as input to said trace math processor.

5. The spectrum analyzer of claim 1 wherein one of said trace mathematical operations generates a trace chosen from the group consisting of an average trace, a maximum trace, a minimum trace, a power difference trace, and a power sum trace.

6. The spectrum analyzer of claim 1 further comprising a specialized function processor, said specialized function processor having an input trace comprising said measured trace or a math trace, to generate a trace that is stored in said trace memory.

7. The spectrum analyzer of claim 6 wherein said specialized function processor commences operations on said input trace prior to all elements of said trace being generated by said math processor or said controller.

8. The spectrum analyzer of claim 1 wherein said traces stored in said trace memory comprise a logarithm of each of said measured amplitudes and wherein said trace math processor operates on said measured amplitudes.

9. The spectrum analyzer of claim 1 wherein one of said trace math programs is input by a user of said spectrum analyzer.
